(19) United States
(12) Patent Application Publication
(10) Pub. No.: US 2026/0060023 A1
(43) Pub. Date: Feb. 26, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventor: Hung-Te Lin, Hsinchu County (TW)

(73) Assignee: Taiwan Semiconductor Manufacturing Company, Ltd., Hsinchu (TW)

(21) Appl. No.: 18/812,919

(22) Filed: Aug. 22, 2024

(51) Int. Cl. H01L 21/78; H01L 21/02; H01L 21/762; H01L 21/768; H01L 23/528; H01L 27/04; H01L 29/34

(52) U.S. Cl. CPC H01L 21/78; H01L 21/76802; H01L 23/5283; H10D 62/57; H10D 84/00; H01L 21/02255; H01L 21/76229

(57) ABSTRACT

A semiconductor device includes a semiconductor substrate including a first side, a second side, a sidewall connected to the first and second sides, and at least one protrusion protruded from the second side, devices disposed at the first side of the semiconductor substrate, and an interconnect structure disposed over the first side of the semiconductor substrate and electrically coupled to the devices. The protrusion and the semiconductor substrate are made of a same material

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductor layers over a semiconductor substrate, and patterning the various layers to form circuit and elements thereon. A great number of integrated circuits are manufactured on a single semiconductor wafer. The individual dies are singulated by sawing the semiconductor wafer along the scribe lanes. Although existing singulation methods have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6A, 7-10A, and 11-15 are schematic cross-sectional views illustrating a method of forming semiconductor devices from a semiconductor substrate at various stages, in accordance with some embodiments.

FIG. 6B is a schematic plane view taken along the line A-A shown in FIG. 6A, in accordance with various embodiments.

FIGS. 10B-10D are schematic different top views illustrating the structure shown in FIG. 10A, in accordance with various embodiments.

FIGS. 10E-10G are schematic different top views illustrating the configuration of various device regions in the semiconductor substrate, in accordance with various embodiments.

FIG. 16 is a schematic graph illustrating the relationship between silicon and oxygen profile in the semiconductor substrate and the thickness, in accordance with some embodiments.

FIGS. 17A-17C are schematic different cross-sectional views illustrating a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure provide novel methods of singulating semiconductor devices and structures thereof, wherein insulating regions and insulating vias connected to the insulating regions are formed in the semiconductor substrate to surround device regions, and then one or more etching process may be performed to remove the insulating regions and the insulating vias so as to separate the device regions from one another, thereby forming semiconductor devices. In this way, the respective semiconductor device may have smoother sidewalls which are formed by etching as compared to the singulated sidewalls formed by sawing/dicing. The conventional scribe lanes and/or the seal-ring structure can be omitted. Since the conventional scribe lines and/or the seal-ring structure can be omitted, the area saved from them can be used for the enlargement of the device region of the respective semiconductor device.

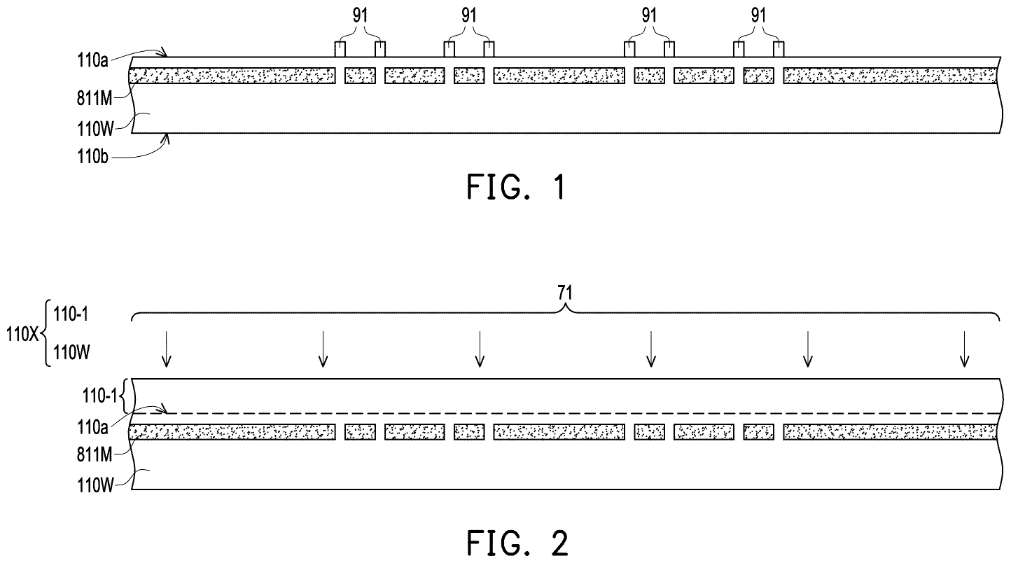

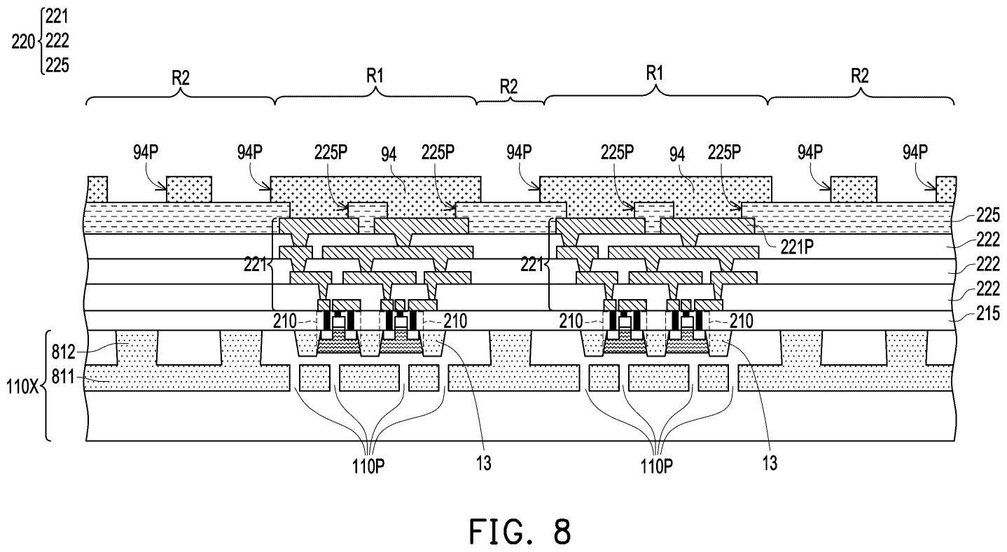

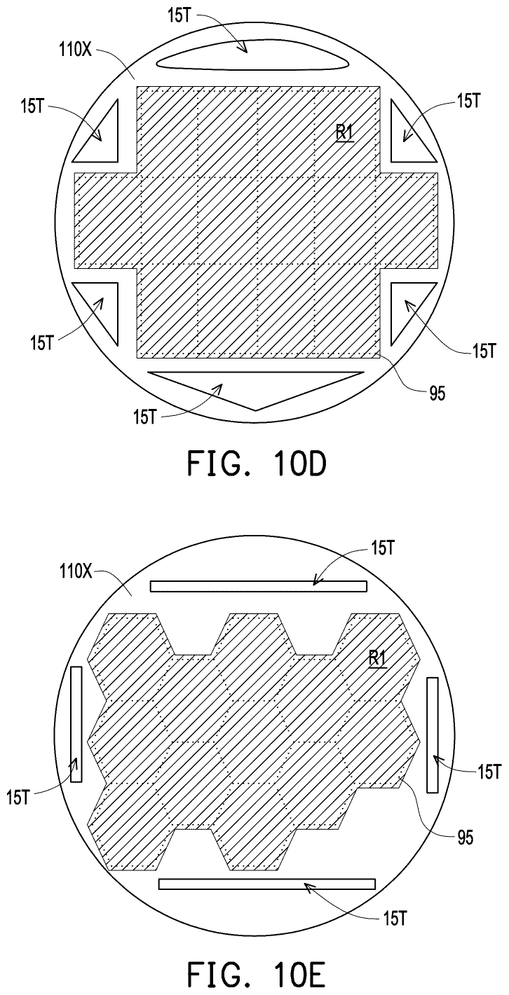

FIGS. 1-6A, 7-10A, and 11-15 are schematic cross-sectional views illustrating a method of forming semiconductor devices from a semiconductor substrate at various stages, FIG. 6B is a schematic plane views taken along the line A-A shown in FIG. 6A, FIGS. 10B-10D are schematic different top views illustrating the structure shown in FIG. 10A, FIGS. 10E-10G are schematic different top views illustrating the configuration of various device regions in the semiconductor substrate, in accordance with various embodiments. Although method embodiments are discussed as being performed in a particular order, other embodiments may be performed in any logical order.

Referring to FIG. 1, a patterned mask layer 91 may be formed on a semiconductor substrate 110W. The semiconductor substrate 110W may be provided in wafer form, panel form, or other suitable form. In an embodiment, the semiconductor substrate 110W is a silicon wafer. The semiconductor substrate 110W may alternatively or additionally include other elementary semiconductor (e.g., germanium), a compound semiconductor (e.g., silicon carbide, gallium arsenic, gallium phosphide, indium phosphide, indium arsenide, and/or indium antimonide, etc.), an alloy semiconductor (e.g., SiGe, GaAsP, AlInAs, AlGaAs, GaInAs, GaInP, GaInAsP, etc.), or combinations thereof. Other semiconductor substrate, such as a multi-layered or gradient substrate, may also be used. The semiconductor substrate 110W may include a first side 110a and a second side 110b opposite to the first side 110a.

The patterned mask layer 91 may be formed on the first side 110a of the semiconductor substrate 110W. In some embodiments, the patterned mask layer 91 includes a patterned photoresist layer which is formed by a lithography process. For example, the lithography process includes forming a photoresist material layer, exposing the photoresist material layer by an exposure process, performing a post-exposure bake process, and developing the photoresist material layer to form the patterned photoresist layer. Alternatively, the patterned mask layer 91 may be formed by depositing a hard mask material, forming a patterned photoresist layer over the hard mask material by a lithography process and etching the hard mask material through the patterned photoresist layer to form the patterned mask layer 91.

With continued reference to FIG. 1, implanted regions 811M may be formed below the first side 110a of the semiconductor substrate 110W. For example, the semiconductor substrate 110W is subjected to implantation of a dielectric material into exposed portions of the semiconductor substrate 110W, forming the implanted regions 811M. The patterned mask layer 91 may be configured to protect regions not intended to be exposed to the implantation process. In some embodiments, an oxygen implant process is performed, and the implanted regions 811M are referred to as implanted oxygen regions. For example, oxygen ions are implanted at a dose of about 5*10¹⁴ atoms/cm² to about 5*10¹⁸ atoms/cm². If the oxygen ions are implanted under the dose of about 5*10¹⁴ atoms/cm², the subsequently-formed insulating regions (e.g., silicon oxide) may be too thin to perform the following processes. Due to the limitation of the manufacturing tools, the oxygen ions may not be implanted over the dose of about 5*10¹⁸ atoms/cm². In some other embodiments, a nitrogen implant process is performed, and the implanted regions 811M are referred to as implanted nitrogen regions. Other suitable ions (e.g., carbon ions, a combination of oxygen ions and nitrogen ions, a combination of oxygen ions and carbon ions, etc.) may be implanted to form the implanted regions 811M. Since the implanted regions 811M are formed below the first side 110a of the semiconductor substrate 110W, the implanted regions 811M may be referred to as a buried dielectric layer. In some embodiments, after the formation of the implanted regions 811M, the patterned mask layer 91 is removed by any suitable process (e.g., stripping, ashing, peeling, etc.).

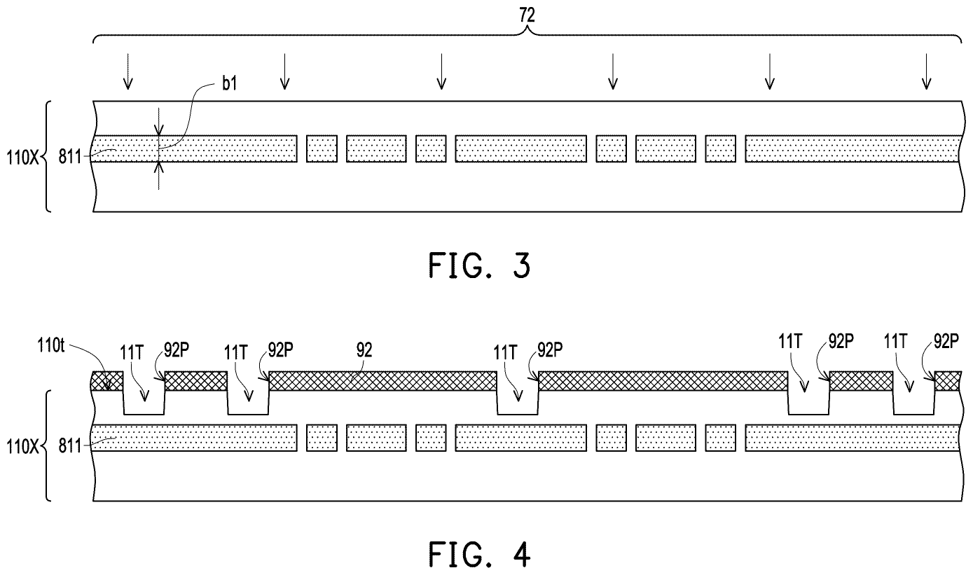

Referring to FIG. 2 and with reference to FIG. 1, an epitaxial process 71 is optionally performed to grown a substrate material layer 110-1 on the first side 110a of the semiconductor substrate 110W. For example, the epitaxial process includes chemical vapor deposition (CVD) (e.g., vapor-phase epitaxy (VPE) and/or ultra-high vacuum CVD (UHV-CVD)), molecular beam epitaxy, and/or other suitable process. In some embodiments, the substrate material layer 110-1 is made of the semiconductor material (e.g., silicon) same as the material of the underlying semiconductor substrate 110W, and no visible interface is formed therebetween. Alternatively, the substrate material layer 110-1 and the underlying semiconductor substrate 110W are made of different semiconductor materials (e.g., silicon and silicon-germanium), and thus a visible interface is formed therebetween. The dashed line shown in FIG. 2 indicates that the interface may or may not exist. The thickness of the substrate material layer 110-1 is not limited in the disclosure, which depends on the type of the active/passive devices subsequently-formed thereon. The substrate material layer 110-1 and the semiconductor substrate 110W may be collectively viewed as a semiconductor substrate 110X. In some other embodiments where the semiconductor substrate 110W is thick enough to form the active/passive devices thereon, the epitaxial process for forming the substrate material layer 110-1 is omitted.

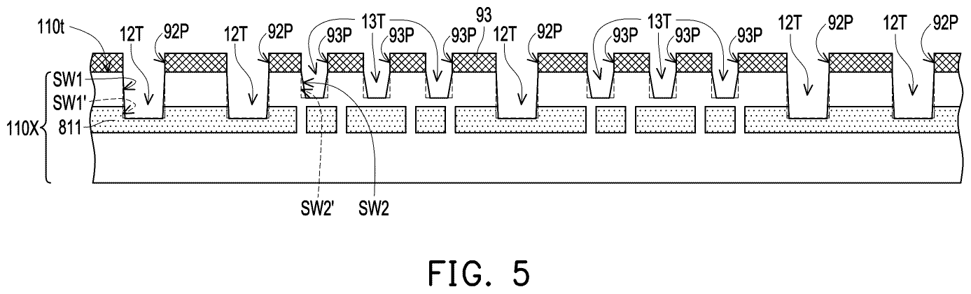

Referring to FIG. 3 and with reference to FIG. 2, a thermal treatment 72 may be performed on the implanted regions 811M to form insulating regions 811. For example, an annealing process is performed to convert the implanted region 811M in the semiconductor substrate 110X into the insulating regions 811. In some embodiments where the implanted regions 811M are formed by oxygen implantation, the insulating regions 811 is referred to as an oxide region containing, e.g., silicon oxide. In some embodiments where the insulating regions 811 include other implant ions (e.g., nitrogen ions, carbon ions, etc.), the insulating regions 811 may be or include silicon nitride, silicon carbide, silicon carbonitride, silicon oxynitride, silicon oxycarbide, and/or the like. In some embodiments, the respective insulating region 811 is formed with a thickness b1 substantially equal to or greater than 0.2 μm. It is realized that the thickness of the insulating regions 811 is an example, and depending on the implant energy and duration, the insulating regions 811 may be made thinner or thicker.

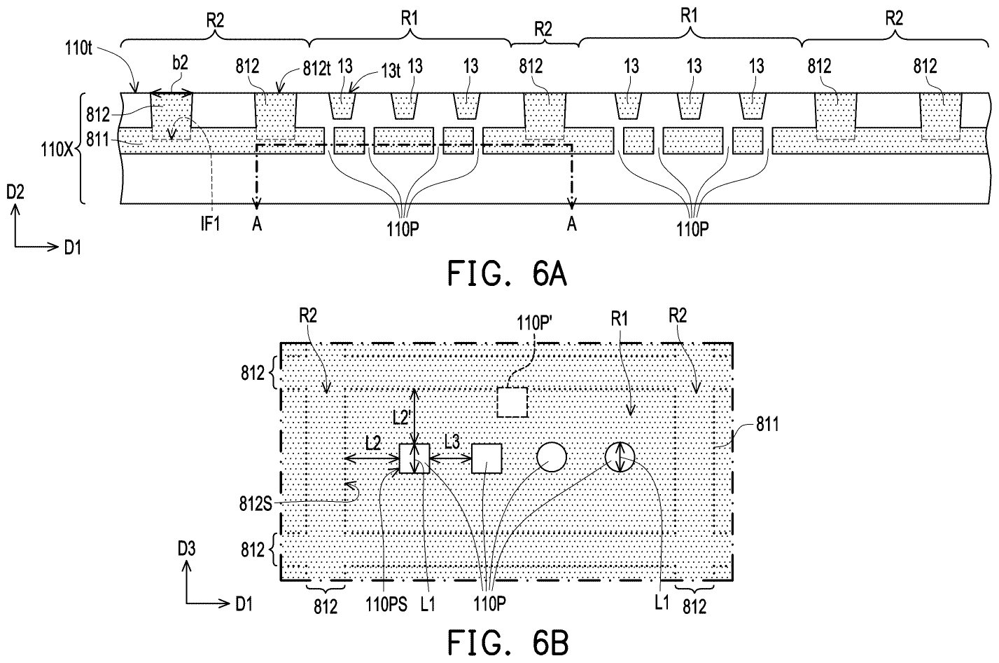

Referring to FIG. 4 and with reference to FIG. 3, a patterned mask layer 92 with openings 92P may be formed on the top surface 110t of the semiconductor substrate 110X. The material and the forming process of the patterned mask layer 92 may be similar to those of the patterned mask layer 91 described in FIG. 1, and thus the detailed descriptions are not repeated herein. With continued reference to FIG. 4, the portions of the semiconductor substrate 110X exposed by the openings 92P of the patterned mask layer 92 may be removed to form trenches 11T in the semiconductor substrate 110X. For example, one or more etching process is performed to form the trenches 11T in the semiconductor substrate 110X, where the patterned mask layer 92 acts as an etch mask. Other suitable removal process may be performed to form the trenches 11T. In some embodiments, the respective trench 11T does not pass through (or reach) the insulating regions 811. In some embodiments, the respective trench 11T is tapered from the top surface 110t of the semiconductor substrate 110X, where the inner sidewall of the semiconductor substrate 110X which defines the respective trench 11T is inclined. In alternative embodiment, the respective trench 11T has a substantially rectangular cross-section, where the inner sidewall of the semiconductor substrate 110X which defines the respective trench 11T is substantially straight.

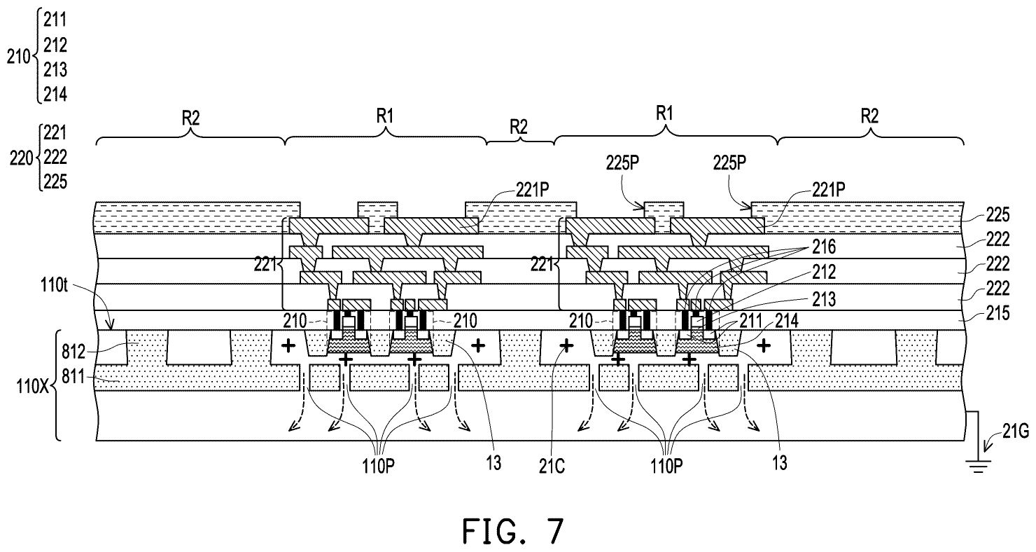

Referring to FIG. 5 and with reference to FIG. 4, a patterned mask layer 93 with the openings 93P and the openings 92P may be formed on the top surface 110t of the semiconductor substrate 110X. In some embodiments, the patterned mask layer 93 is formed by patterning the patterned mask layer 92 to form the openings 93P. In alternative embodiments, the patterned mask layer 92 is first removed, and the patterned mask layer 93 having the openings 93P and the openings 92P is then formed on the semiconductor substrate 110X, where each of the openings 92P is substantially aligned with one of the trenches 11T. In some other embodiments, the step described in FIG. 4 is omitted.

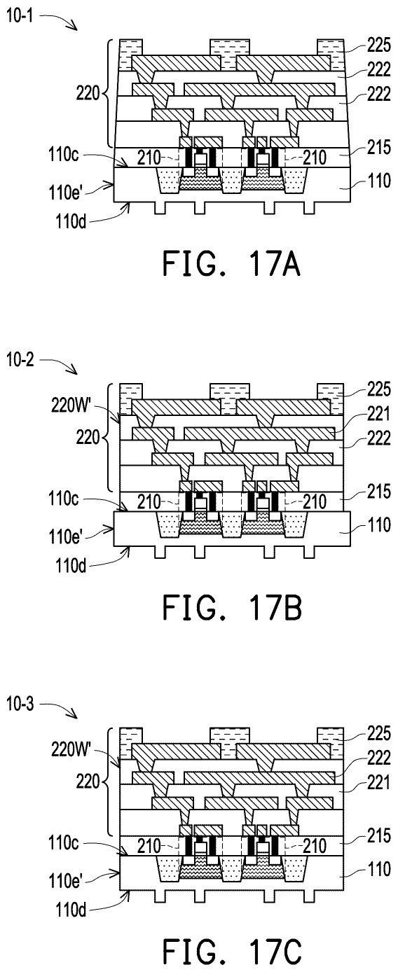

After the formation of the patterned mask layer 93, one or more etching process may be performed to remove portions of the semiconductor substrate 110X exposed by the openings 93P and the openings 92P. For example, the portions of the semiconductor substrate 110X exposed by the openings 92P are etched, until the insulating regions 811 is exposed by the trenches 12T. In some embodiments, the respective trench 12T is tapered from the top surface 110t of the semiconductor substrate 110X, where the inner sidewall SW1 of the semiconductor substrate 110X which defines the respective trench 12T is inclined. In alternative embodiment, the respective trench 12T has a substantially rectangular cross-section, where the inner sidewall SW1′ of the semiconductor substrate 110X which defines the respective trench 11T is substantially straight. Note that the following steps (e.g., FIGS. 6A-15) are described based on the semiconductor substrate 110X having the inner sidewall SW1; however, in some embodiments (e.g., FIGS. 17A-17C), the resulting structure may be formed by the semiconductor substrate 110X having the inner sidewall SW1′.

With continued reference to FIG. 5, the portions of the semiconductor substrate 110X exposed by the openings 93P may be removed (e.g., during the etching process) to form the trenches 13T. The respective trench 13T may not extend through (or reach) the underlying insulating regions 811. The depth of the respective trench 13T may be less than the depth of the respective trench 12T. Similar to the trenches 12T, the respective trench 13T may be defined by the inclined inner sidewall SW2 of the semiconductor substrate 110X or may be defined by the straight inner sidewall SW2′ of the semiconductor substrate 110X. Note that the following steps (e.g., FIGS. 6A-15) are described based on the semiconductor substrate 110X having the inner sidewall SW2; however, in some embodiments, the resulting structure (not shown) may be formed by the semiconductor substrate 110X having the inner sidewall SW2′.

Referring to FIG. 6A and with reference to FIG. 5, the trenches 12T may be filled with insulating vias 812 through any suitable disposition process (e.g., CVD, physical vapor deposition (PVD), atomic layer deposition (ALD), etc.). The material of the insulating vias 812 may be or include an oxide (e.g., silicon oxide), a nitride (e.g., silicon nitride), carbide (e.g., silicon carbide), silicon carbonitride, silicon oxynitride, silicon oxycarbide, the like, a combination thereof, and/or the like. In some embodiments, the material of the insulating vias 812 is the same as the material of the insulating regions 811, and thus no visible interface is formed therebetween. In some other embodiments, the material of the insulating vias 812 is different from the material of the insulating regions 811, and thus a visible interface IF1 is formed therebetween. The interface IF1 is shown in the dashed lines to indicate it may or may not exist.

With continued reference to FIGS. 5-6A, since the respective trench 12T exposes at least a portion of the insulating regions 811, the insulating vias 812 formed in the trenches 12T may be in physical contact with the insulating regions 811. The insulating regions 811 may extend along a first direction D1 (e.g., the x-direction or the y-direction), while the insulating vias 812 may extend along a second direction D2 (e.g., the z-direction) which is substantially perpendicular to the first direction D1. In some embodiments, the maximum lateral dimension b2 of the respective insulating via 812 measured along the first direction D1 is greater than 0.2 μm. The maximum lateral dimension b2 of the respective insulating via 812 and the thickness b1 of the insulating regions 811 (see FIG. 3) may be the same or may be different, depending on process requirements.

With continued reference to FIGS. 5-6A, trenches 13T may be filled with an insulating material to form shallow trench isolation (STI) regions 13 through any suitable disposition process (e.g., CVD, PVD, ALD, etc.). In some embodiments, the STI regions 13 and the insulating vias 812 are made of the same material and formed during the same deposition process. In some other embodiments, the STI regions 13 and insulating vias 812 are made of the different dielectric materials and/or are formed at the different deposition processes. In some embodiments, the patterned mask layer 93 is removed after filling the trenches 12T and 13T with the insulating material(s). In some embodiments, a planarization process (e.g., chemical mechanical polishing (CMP), grinding, etching, a combination thereof, etc.) is performed so that the top surfaces (812t and 13t) of the insulating vias 812 and the STI regions 13 are substantially leveled (or coplanar) with the top surface 110t of the semiconductor substrate 110X, within process variations.

Referring to FIGS. 6A-6B, the STI regions 13 may be distributed within a device region R1 of the semiconductor substrate 110X, and the insulating vias 812 may be distributed within a sacrificial region R2 of the semiconductor substrate 110X. The device region R1 may be encircled by the sacrificial region R2 as shown in the plane views of FIG. 6B. The subsequently-formed interconnect wirings and devices may be disposed within the device region R1, and the structure formed in the sacrificial region R2 may be considered sacrificial in the sense that it may be ultimately removed.

With continued reference to FIGS. 6A-6B, the line A-A shown in FIG. 6A extends across the device region R1 and into the sacrificial region R2, and the line A-A shown in FIG. 6A is located within the insulating regions 811 and across the pillar portions 110P of the semiconductor substrate 110X surrounded by the insulating regions 811. FIG. 6B is a schematic plane view taken along the line A-A shown in FIG. 6A. In some embodiments, the pillar portions 110P are distributed within the device region R1. The pillar portions 110P may be configured to release the charges generated during the subsequently-performed processing into a ground electrical potential. Note that the locations of the pillar portions 110P are defined by the patterned mask layer 91 (see FIG. 1). The amount of the pillar portions 110P may be one or more than one, depending on process requirements. The top-view shape(s) of the pillar portion 110P may be or include a rectangular shape, a square shape, a polygon shape, a circular shape, an oval shape, an irregular shape, a combination thereof, etc. It should be also noted that the locations, the shape, and the number of the pillar portions 110P shown in FIGS. 6A-6B are merely examples and construe no limitation in the disclosure.

With continued reference to FIG. 6B, the respective pillar portion 110P may have a lateral dimension (e.g., a diameter, a length, or a width) L1 ranging from about 0.1 μm to about 100 μm. In some embodiments, the minimum distance L2 measured from the sidewall 110PS of the pillar portion 110P to the sidewall 812S of the closest insulating via 812 is about 0.1 μm. The minimum distance L2 is measured along the first direction D1. The minimum distance L2′ measured along the third direction D3 may be the same as (or different from) the minimum distance L2, where the first direction D1 is substantially perpendicular to the third direction D3. The first direction D1 may be the x-direction (or the y-direction) and the third direction D3 may be the y-direction (or the x-direction). In some embodiments, the minimum distance L2 (or L2′) is about 0, where the sidewall 110PS of the pillar portion 110P′ is substantially aligned with the sidewall 812S of the closest insulating via 812. The pillar portions 110P may be arranged along the first direction D1 and separated from each other by a lateral distance L3. The lateral distance L3 may be non-zero, for example, at least 0.5 μm. It is realized that the values provided above are examples, and may be changed to other suitable values depending on process and product requirements.

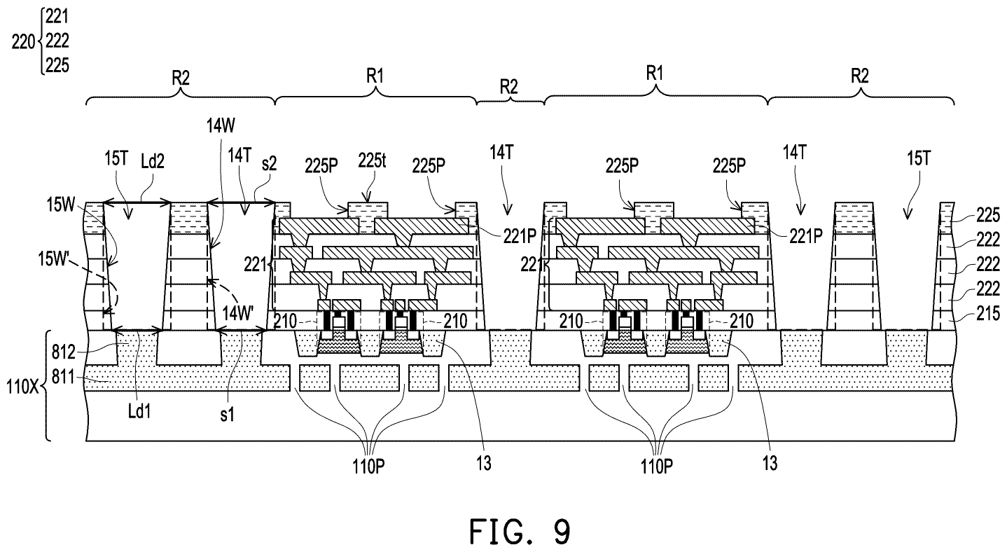

Referring to FIG. 7 and with reference to FIG. 6A, devices (represented by a transistor) 210 may be formed at the top surface 110t of the semiconductor substrate 110X. The devices 210 may be or include active devices (e.g., transistors, diodes, etc.), passive devices (e.g., capacitors, resistors, inductors, etc.), a combination thereof, or the like. The devices 210 may be separated by the STI regions 13 located between two adjacent devices 210. For example, the semiconductor substrate 110X includes various doped regions depending on circuit requirements (e.g., p-type semiconductor substrate or n-type semiconductor substrate). The doped regions may be doped with p-type or n-type dopants. In some embodiments, the doped regions serve as source/drain (S/D) regions 211 of the device 210 formed in the semiconductor substrate 110X. Note that S/D region(s) may refer to a source or a drain, individually or collectively dependent upon the context. Depending on the types of the dopants in the doped regions, the device 210 may be referred to as an n-type transistor or a p-type transistor. In some embodiments, the device 210 includes a metal gate 212, a gate dielectric 213 underlying the metal gate 212, and a channel 214 under the gate dielectric 213. The channel 214 may be between the S/D regions 211 to serve as a path for electrons to travel when the device 210 is turned on. In some embodiments, the device 210 is formed using suitable Front-end-of-line (FEOL) process. For simplicity, four devices 210 are shown; however, it should be understood that the number of the devices 210 depending on the application of the resulting semiconductor device.

With continued reference to FIG. 7, an inter-layer dielectric (ILD) 215 may be formed over the top surface 110t of the semiconductor substrate 110X. The ILD 215 may surround and cover the devices 210. The ILD 215 may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), the like, or combinations thereof. Conductive plugs 216 may extend through the ILD 215 to electrically and physically couple to the devices 210. For example, when the devices 210 are transistors, the conductive plugs 216 may couple the metal gate 212 and the S/D regions 214. The conductive plugs 216 may be formed of tungsten, cobalt, nickel, copper, silver, gold, aluminum, the like, or combinations thereof. In some embodiments, the ILD 215 and the conductive plugs 216 are formed using suitable middle-end-of-line (MEOL) process.

With continued reference to FIG. 7, an interconnect structure 220 may be formed over the ILD 215 and conductive plugs 216. The interconnect structure 220 may interconnect the devices 210 to form an integrated circuit. In some embodiments, the interconnect structure 220 is formed using suitable Back-end-of-line (BEOL) process. The interconnect structure 220 may be formed of alternating layers of dielectric (e.g., low-k dielectric material) and conductive material (e.g., copper) with vias interconnecting the layers of conductive material and may be formed through any suitable process (e.g., deposition, damascene, etc.). For example, the interconnect structure 220 includes metallization patterns 221 formed in dielectric layers 222. The dielectric layers 222 may include one or more low-k dielectric material(s) or any suitable dielectric material(s), and may be referred to as an inter-metal dielectric (IMD). The metallization patterns 221 may include conductive pads, conductive lines, conductive vias, etc., and may be electrically coupled to the devices 210 through the conductive plugs 216. The topmost one of the metallization patterns 221 may include contact pads 221P (e.g., aluminum pads, copper pads, copper-aluminum pads, etc.) for external connections. The interconnect structure 220 may include a passivation layer 225 with openings 225P formed on the topmost one of the dielectric layers 222, and the openings 225P may expose at least a portion of the contact pads 221P. In some embodiments, the passivation layer 225 includes one or more layers of silicon oxide, silicon nitride, silicon oxynitride, the like, or a combination thereof.

With continued reference to FIG. 7, during the FEOL process, the MEOL process, and the BEOL process, the pillar portions 110P may be configured to release (see the dashed arrows) the charges 21C generated during the processing into a ground electrical potential 21G. With no accumulated charges in the structures over the semiconductor substrate 110X, the circuits (e.g., the metallization patterns 221) and the devices 210 may be protected, and damages to the circuits and the devices from the charging effect may be reduced. The fabrication process may be more stable without the accumulated charges.

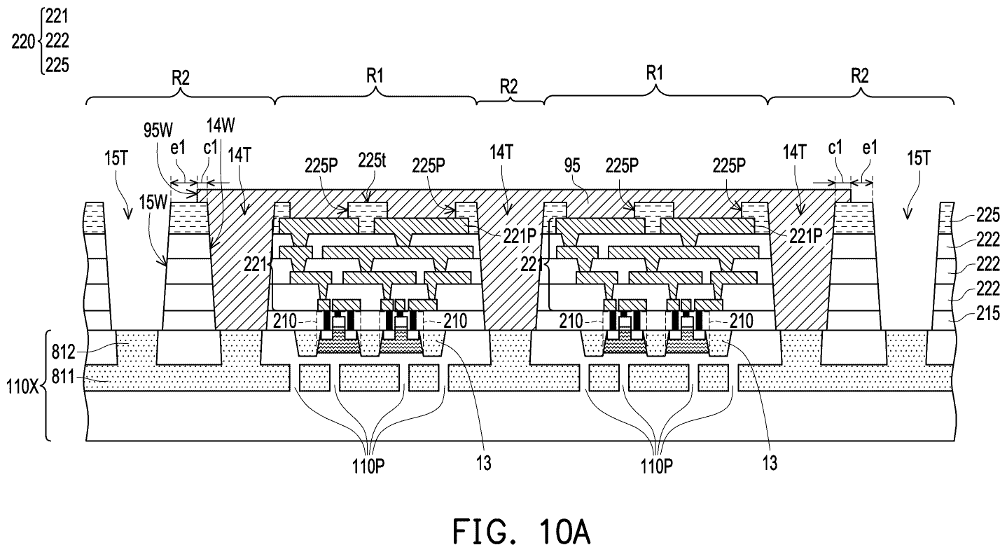

Referring to FIG. 8 and with reference to FIG. 7, a patterned mask layer 94 with openings 94P may be formed over the interconnect structure 220. In some embodiments, the device regions R1 are fully covered by the patterned mask layer 94, and the patterned mask layer 94 may extend into the passivation layer 225 to be in contact with the portions of the contact pads 221P which were exposed by the openings 225P of the passivation layer 225. The openings 94 of the patterned mask layer 94 may be located within the sacrificial region R2. In some embodiments, the patterned mask layer 94 includes one or more passivation material(s). In some embodiments, the patterned mask layer 94 is made of a photoresist and formed by the method similar to the formation of the patterned mask layer 91.

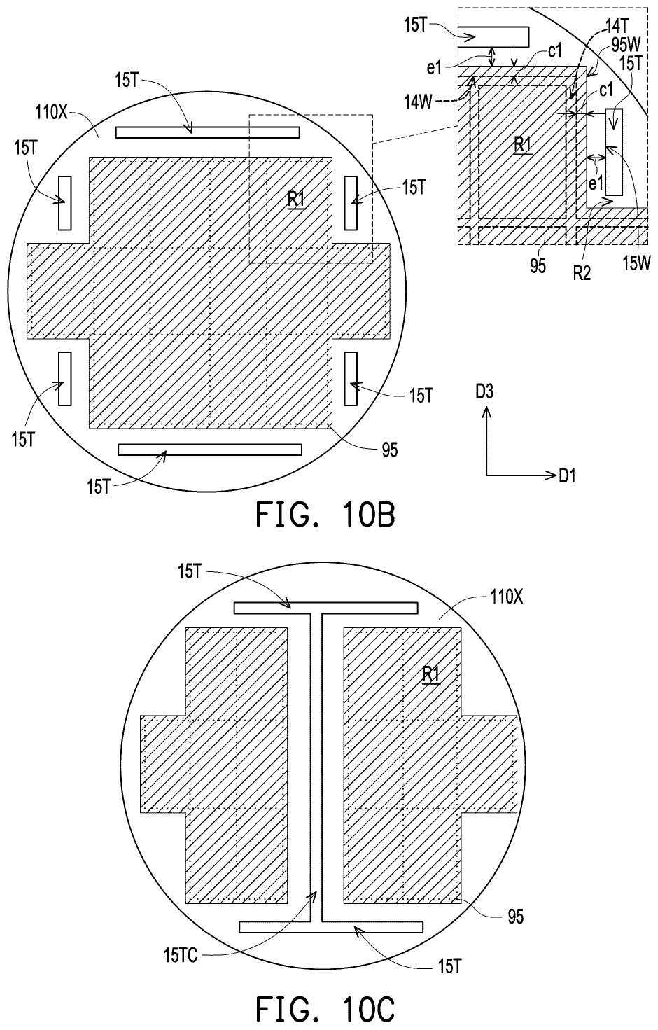

Referring to FIG. 9 and with reference to FIG. 8, trenches 14T and windows 15T may be formed in the sacrificial region R2 by using the openings 94P of the patterned mask layer 94. The trenches 14T may encircle the device region R1 and may be in communication with each other in the top view (see FIGS. 10B-10D). The windows 15T may be formed outside the array of the device regions R1 and located at the blank area of the semiconductor substrate (see FIGS. 10B-10D). The windows 15T may be in communication with each other or may be discontinuously distributed over the semiconductor substrate 110X (see FIGS. 10B-10D). For example, one or more etching process is performed to remove portions of the passivation layer 225, the dielectric layers 222, and the ILD 215, until at least a portion of the insulating vias 812 is exposed by the trenches 14T and the windows 15T. After forming the trenches 14T and the windows 15T, the patterned mask layer 94 may be removed by any suitable process (e.g., stripping, ashing, peeling, etc.). Once the patterned mask layer 94 is removed, the contact pads 221P may be exposed.

In some embodiments, each or some of the trenches 14T and the windows 15T may be tapered from the passivation layer 225 toward the corresponding insulating via 812, where the inner sidewall 14W which defines the respective trench 14T is inclined, and the inner sidewall 15W which defines the respective window 15T is inclined. For example, the respective trench 14T has the minimum lateral dimension s1 at the bottom and the maximum lateral dimension s2 at the top, where the maximum lateral dimension s2 is greater than the minimum lateral dimension s1. In some embodiments, the minimum lateral dimension s1 is greater than (or substantially equal to) the maximum lateral dimension b2 (see FIG. 6A) of the corresponding insulating via 812. Similarly, the respective window 15T may have the minimum lateral dimension Ld1 at the bottom and the maximum lateral dimension Ld2 at the top, where the maximum lateral dimension Ld2 is greater than the minimum lateral dimension Ld1. For example, the maximum lateral dimension Ld2 is about 0.5 μm. In some embodiments, the minimum lateral dimension Ld1 is greater than (or substantially equal to) the maximum lateral dimension b2 (see FIG. 6A) of the corresponding insulating via 812.

In alternative embodiment, each or some of the trenches 14T and the windows 15T may have a substantially rectangular cross-section, where the inner sidewall 14W′ which defines the respective trench 14T and the inner sidewall 15W′ which defines the respective window 15T are substantially straight. For example, the maximum lateral dimension s2 and the minimum lateral dimension s1 of the respective trench 14T are substantially equal to each other. The minimum lateral dimension s1 may be greater than or substantially equal to the maximum lateral dimension b2 (see FIG. 6A) of the corresponding insulating via 812. Similarly, the maximum lateral dimension Ld2 and the minimum lateral dimension Ld1 of the respective window 15T may be substantially equal to each other. The minimum lateral dimension Ld1 may be greater than or substantially equal to the maximum lateral dimension b2 (see FIG. 6A) of the corresponding insulating via 812. Note that the following steps (e.g., FIGS. 10A and 11-15) are described based on the slanted inner sidewall (14W and 15W); however, in some embodiments (e.g., FIGS. 17B-17C), the resulting structure may be formed by the straight inner sidewall 14W′.

Referring to FIG. 10A and with reference to FIG. 9, a protective layer 95 may be formed over the device regions R1 and extend to cover a portion of the sacrificial region R2 near the device regions R1 using suitable deposition process (e.g., a spin-coating process or the like). In some embodiments, the protective layer 95 is formed of a dielectric material provided in a glue form. The material of the protective layer 95 may be different from the underlying insulating vias 812. Any suitable protective material(s) and suitable form may be used. For example, the protective layer 95 is partially formed on the top surface 225t of the passivation layer 225, extend into the openings 225P to be in contact with the contact pads 221P, and extend into the trenches 14T to be in contact with the underlying insulating vias 812. The protective layer 95 does not extend to cover the windows 15T, and thus the insulating vias 812 underlying the windows 15T may remain exposed by the windows 15T.

Referring to FIG. 10B and with continued reference to FIG. 10A, the portion of the protective layer 95 formed on the top surface 225t of the passivation layer 225 and extending into the sacrificial region R2 may have a lateral dimension c1 measured along the first direction D1 and/or the third direction D3. For example, the lateral dimension c1 is measured from the intersection of the inner sidewall 14W (or 14W′) and the top surface 225t of the passivation layer 225 to the outer sidewall 95W of the protective layer 95. The lateral dimension c1 may be non-zero (e.g., greater than 0 or greater than 10 μm). The non-zero lateral dimension c1 may ensure that the respective device region R1 and the trenches 14T encircling the respective device region R1 are covered by the protective layer 95. The lateral distance e1 measured along the first direction D1 and/or the third direction D3 may be between the outer sidewall 95W of the protective layer 95 and the intersection of the inner sidewall 15W (or 15W′) and the top surface 225t of the passivation layer 225. For example, the lateral distance e1 is non-zero (e.g., greater than 0 or greater than 5 μm). The non-zero lateral distance e1 may ensure that the windows 15T are exposed by the protective layer 95.

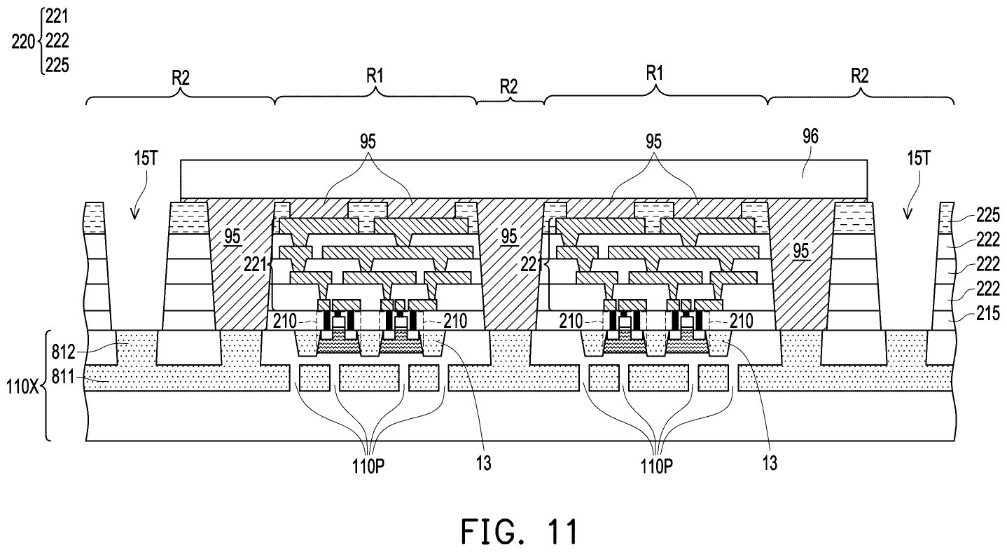

Referring to FIGS. 10C-10D and with reference to FIG. 10B, the configuration shown in FIG. 10C is similar to the configuration shown in FIG. 10B, except that the windows 15T shown in FIG. 10C are in communication with each other through the central window 15TC, and the device regions R1 are disposed at two opposing sides of the central window 15TC. By disposing the central window 15T in the central area of the semiconductor substrate 110X, the removal uniformity may be improved and/or the process time may be reduced during the subsequently-performed removing process (see FIG. 12). The configuration shown in FIG. 10D may be similar to the configuration shown in FIG. 10B, except that the windows 15T in FIG. 10D may have a polygonal (or irregular/triangle) top-view shape. It is noted that the shapes, the number, and the locations of the windows 15T illustrated herein are merely examples and construe no limitation in the disclosure.

Referring to FIGS. 10E-10G, the configurations shown in FIGS. 10E-10G may be similar to the configuration shown in FIG. 10B, except that the top-view shape of each device region R1 may not be identical to one another. In some embodiments, as shown in FIG. 10E, the device regions R1 are arranged in honeycomb pattern, where each of the device regions R1 may have a hexagonal top-view shape. In some embodiments, as shown in FIG. 10F, the device regions R1 have rectangular top-view shapes with varying surface areas. In some embodiments, as shown in FIG. 10G, the device regions R1 have the rectangular top-view shape and the device regions R1′ have the cross top-view shape. It is noted that the shapes, the number, and the configurations of the device regions R1/R1′ illustrated herein are merely examples and construe no limitation in the disclosure.

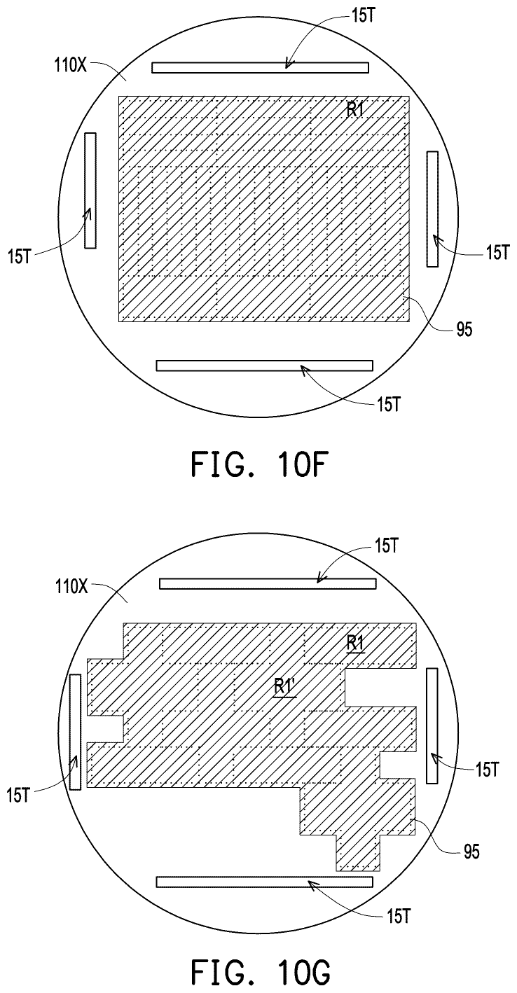

Referring to FIG. 11 and with reference to FIG. 10A, a temporary carrier 96 may be attached to the protective layer 95. The temporary carrier 96 may be provided with a release layer (e.g., light-to-heat-conversion (LTHC) layer or any suitable adhesive layer; not shown), and the protective layer 95 is bonded to the temporary carrier 96 through the release layer. In some embodiments, the temporary carrier 96 is directly adhered to the protective layer 95. The material of the temporary carrier 96 may include silicon (e.g., bulk silicon), glass, metal (e.g., steel), ceramic, combinations thereof, multi-layers thereof, or the like. The temporary carrier 96 may cover each of the device regions R1 and may partially cover the sacrificial region R2. The windows 15T may not be covered by the temporary carrier 96. It is noted that the shape and the material of the temporary carrier 96 construe no limitation in the disclosure.

In some embodiments where the protective layer 95 is provided in a gel form, during the bonding of the temporary carrier 96, the protective layer 95 is pressed to fill the openings 225P and the trenches 14T. In some embodiments, the portions of the protective layer 95 on the top surface 225t of the passivation layer 225 are moved to fill the openings 225P and the trenches 14T. For example, the portions of the protective layer 95 on the top surface 225t of the passivation layer 225 become very thin due to the compressive force from the attachment of the temporary carrier 96. Alternatively, a majority of the portions of the protective layer 95 on the top surface 225t of the passivation layer 225 is moved to fill the openings 225P and the trenches 14T, and a few (or negligible) amount of the portions of the protective layer 95 is left on the top surface 225t of the passivation layer 225.

Referring to FIG. 12 and with reference to FIG. 11, one or more removal process (e.g., wet etching or the like) may be performed to remove the insulating vias 812 and the insulating regions 811 through the windows 15T. Since the windows 15T expose the insulating vias 812 and the insulating vias 812 are connected to one another through the insulting regions 811, the etchant may reach the insulating vias 812 through the windows 15T to remove the insulating vias 812 and the underlying insulating regions 811. The windows 15T may be referred to as etch windows. In some embodiments where the insulating vias 812 and the insulating regions 811 are formed of the same material, the insulating vias 812 and the insulating regions 811 are removed during a single etching step. In some embodiments where the insulating vias 812 and the insulating regions 811 are formed of different materials, multiple etching steps are performed.

With continued reference to FIG. 12, after the removal of the insulating vias 812 and the insulating regions 811, a force 73 (e.g., supersonic waves or other suitable mechanical force) may be applied to the pillar portions 110P to separate the redundant portion of the semiconductor substrate 110X and the dielectric structure formed thereon. For example, the portion of the structure attached to the temporary carrier 96 is left, while the portion of the semiconductor substrate 110X underlying the pillar portions 110P and the other portion of the structure which is not covered by the temporary carrier 96 are removed after breaking the pillar portions 110P.

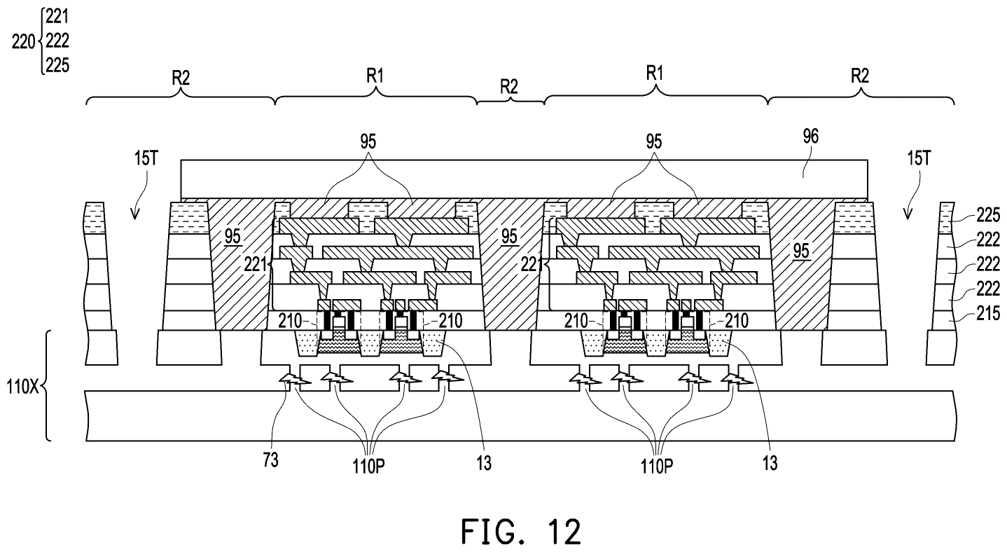

Referring to FIG. 13 and with reference to FIG. 12, a portion of the protective layer 95 which is exposed by the trenches 12T′ may be removed to form the trenches 14T′, where the trenches 12T′ are formed by removing the insulating vias 812 as described in FIG. 12. For example, a selective wet etching process (e.g., a chemical etching process or the like) is performed to remove the protective layer 95.

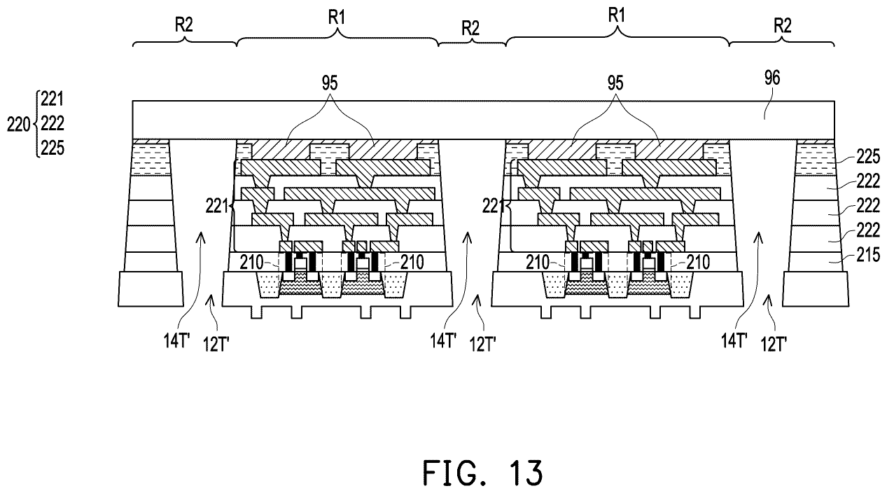

Referring to FIG. 14 and with reference to FIG. 13, the temporary carrier 96 may be removed to reveal the rest portion of the protective layer 95, and then the rest portion of the protective layer 95 may be removed to reveal the contact pads 221P and the top surface 225t of the passivation layer 225. In some embodiments, the temporary carrier 96 is removed through stripping, peeling, etching, a combination thereof, etc. In some embodiments where the temporary carrier 96 is provided with the LTHC layer (not shown), the de-bonding of the temporary carrier 96 includes projecting a light (e.g., laser light or UV light) on the LTHC layer, so that the LTHC layer decomposes under the heat of the light and the temporary carrier 96 and the LTHC layer are removed. In some embodiments where the temporary carrier 96 is provided with an adhesive layer (not shown), a suitable solvent may be used to dissolve the adhesive layer. The redundant structure in the sacrificial region R2 which is attached to the temporary carrier 96 may be removed along with the temporary carrier 96, leaving the device regions R1. Therefore, the device regions R1 are singulated to form a plurality of semiconductor devices.

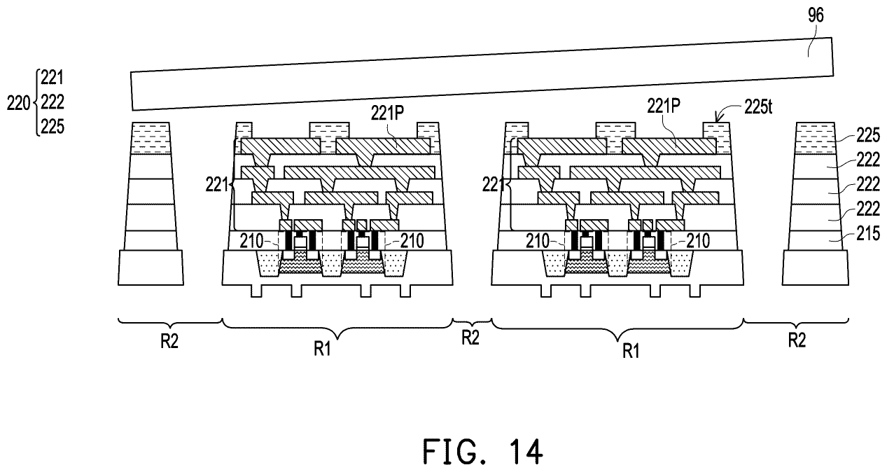

Referring to FIG. 15 and with reference to FIG. 14, each of the semiconductor devices 10 may include a semiconductor substrate 110 formed from the semiconductor substrate 110X, the devices 210 formed in/on the semiconductor substrate 110, the interconnect structure 220 formed over the semiconductor substrate 110 and electrically coupled to the devices 210. The semiconductor substrate 110 may include a first side (or an active side) 110c, a second side (or a back side) 110d opposite to the first side 110c, and a sidewall 110e connected to the first side 110c and the second side 110d. The devices 210 may be formed at the first side 110c of the semiconductor substrate 110.

With continued reference to FIG. 15, at least one protrusion 110P′ may be formed at the second side 110d of the semiconductor substrate 110, where after breaking the pillar portions 110P as described in FIG. 12, the protrusions 110P′ are formed. The lateral dimension (e.g., the width, the length, or the diameter) L4 of the respective protrusion 110P′ measured along the first direction D1 may be less than the lateral dimension L1 (see FIG. 6B) of the pillar portion 110P, since the pillar portions 110P may be laterally etched during the removal of the insulating regions 811 (see FIG. 12). For example, the lateral dimension L4 is in a range of less than 0.1 μm (e.g., about 0.02 μm) to less than 100 μm. The height H1 of the respective protrusion 110P′ measured along the second direction D2 may be non-zero. The height H1 of the respective protrusion 110P′ may be less than the lateral dimension L4 (e.g., less than about 0.2 μm). For example, the minimum height H1 of the respective protrusion 110P′ is about 0.01 μm. A planarization process (e.g., CMP, grinding, etching, a combination thereof, etc.) is optionally performed on the second side 110d of the semiconductor substrate 110 to remove the protrusions 110P′ and planarize the second side 110d of the semiconductor substrate 110.

With continued reference to FIG. 15, the average height 110H of the semiconductor substrate 110 measured between the first side 110c and the second side 110d and measured along the second direction D2 may be in a range of about 0.1 μm and about 500 μm. Since the semiconductor substrate 110 can be very thin (e.g., about 0.1 μm), the semiconductor device 10 may be implemented as an ultra-thin IC chip. The sidewall 110e of the semiconductor substrate 110 may be substantially straight or may be inclined, which depends on the profile of the trenches 12T (see FIG. 5). If the inclined inner sidewall SW1 is formed at the step of FIG. 5, then the resulting semiconductor substrate 110 may have the inclined sidewall 110e as shown in FIG. 15. If the straight inner sidewall SW1′ is formed at the step of FIG. 5, then the resulting semiconductor substrate 110 may have the straight sidewall as shown in FIGS. 17A-17C. The included angle θ between the second side 110d and the sidewall 110e may be a substantially right angle or an acute angle. In some embodiments where the included angle θ is a substantially right angle, the better chip area efficiency may be obtained.

With continued reference to FIG. 15, the semiconductor substrate 110 may be wider than the interconnect structure 220. For example, the sidewall 220W of the interconnect structure 220 is laterally offset from the sidewall 110e of the semiconductor substrate 110. In some embodiments, a lateral dimension L5 measured along the first direction D1 and measured between the sidewall 220W and the sidewall 110e is non-zero. The lateral dimension L5 may be formed due to the difference of the maximum lateral dimension b2 (see FIG. 6A) of the respective insulating via 812 and the minimum lateral dimension Ld1 of the respective window 15T (see FIG. 9). For example, the periphery of the semiconductor substrate 110 with the lateral dimension L5 is exposed by the interconnect structure 220 and the ILD 215. In some embodiments, the interconnect structure 220 is tapered from the bottom to the top, and the sidewall 220W of the interconnect structure 220 is inclined. For example, the top width 220T of the interconnect structure 220 is less than the bottom width 220B of the interconnect structure 220 because of the tapered shape of the trench 14T (see FIG. 9). In some embodiments, the bottom width 220B of the interconnect structure 220 is less than a maximum lateral dimension 110M of the semiconductor substrate 110. However, the semiconductor device may have a different profile as will be described later in accompanying with FIGS. 17A-17C.

As compared to the conventional singulation process using a sawing/laser cutting tool, the singulation method described in FIGS. 1-15 may provide the semiconductor device 10 having a smoother outer sidewall 10W. The outer sidewall 10W including the sidewall 110e and the sidewall 220W may be formed by, e.g., etching. A surface roughness of the sidewall 110e of the semiconductor substrate 110 may be less than that of the second side 110d of the semiconductor substrate 110. In some embodiments, the surface roughness of the sidewall 110e of the semiconductor substrate 110 is less than that of the second side 110d of the semiconductor substrate 110 (with or without being planarized). As compared to the conventional singulation process using a sawing/laser cutting tool, the sidewall 220W of the interconnect structure 220 may be smoother than the sidewall of the IMD which has been singulated by sawing/laser cutting. For example, a surface roughness of the outer sidewall 10W of the semiconductor device 10 is in a range of about 0.1 μm and about 2 μm.

The metallization patterns 221 of the interconnect structure 220 and the devices 210 may be disposed within an active region AR1 of the semiconductor device 10. A blank area BR1 may be located between the active region AR1 and the outer boundary of the semiconductor device 10 defined by the sidewall 10W, where the active region AR1 is encircled by the blank area BR1. For example, a lateral dimension of the blank area BR1 is at least about 0.15 μm. It is realized that the value is an example and may be changed to other suitable value depending on process and product requirements. In some embodiments, no conductive feature is formed in the blank area BR1. For example, the interconnect structure 220 is free of any seal-ring structure formed in the blank area BR1. One of the purposes for forming the seal-ring structure is to prevent the mechanical/thermal stress from damaging the interconnect wirings during the sawing of the singulation process, and a certain area between the edge of the interconnect wirings and the sidewall 220W should be saved for the formation of the seal-ring structure. By using the singulation method described in FIGS. 1-15, there is no need to form the conventional seal-ring structure for preventing the interconnect wirings from damage, since the concerns of the mechanical/thermal stress during the sawing are eliminated.

The conventional singulation process using a sawing/laser cutting tool may need a large area for scribe lanes. By using the singulation method described in FIGS. 1-15, there is no need to reserve the large area for the scribe lanes. The areas may be saved from the omission of the seal-ring structure and the conventional scribe lanes. For example, the saved area is about 10%. By using the singulation method described in FIGS. 1-15, the top-view shape of the semiconductor device 10 (see FIGS. 10E-10G) may be more flexible depending on product requirements.

The respective semiconductor device 10 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

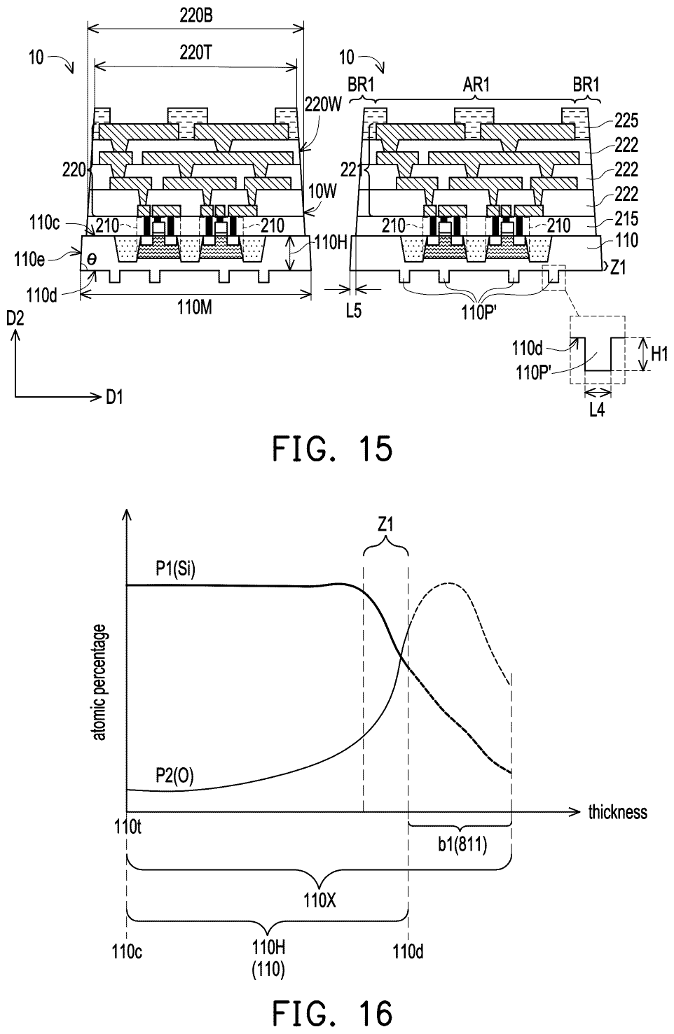

FIG. 16 is a schematic graph illustrating the relationship between silicon and oxygen profile in the semiconductor substrate and the thickness, in accordance with some embodiments. Referring to FIG. 16 and with reference to FIG. 3, a profile P1 is silicon atomic percentage profile of the semiconductor substrate 110X, and a profile P2 is oxygen atomic percentage profile of the semiconductor substrate 110X, according to some embodiments. It should be noted that the profile P2 may be replaced with nitrogen atomic percentage profile, carbon atomic percentage profile, and/or the like, depending on the ions implanted in the regions (see FIG. 3). As described in FIG. 3, the insulating region 811 with the thickness b1 is formed below the top surface 110t of the semiconductor substrate 110X. In some embodiments, a boundary zone Z1 is formed on (or close to) the top of the insulating region 811. In the boundary zone Z1, silicon-rich oxide layer (SiₓO) containing silicon and oxygen may be formed.

As shown in FIG. 16, the silicon atomic percentage may have no significant change in the area above the boundary zone Z1, where the slope of the profile P1 in the area above the boundary zone Z1 may be negligible. In the boundary zone Z1, the profile P1 may decrease downwardly from the top of the boundary zone Z1 to the insulating region 811. In some embodiments where oxygen ions are implanted to form the insulating region 811 having silicon oxide, the oxygen atomic percentage increase along the thickness direction (e.g., the second direction D2) from the top surface 110t of the semiconductor substrate 110X toward the insulating region 811. In the boundary zone Z1, the profile P1 may have a negative slope and the profile P2 may have a positive slope. The profile P2 may have a steeper slope in the boundary zone Z1 than in the area above the boundary zone Z1. The peak of the profile P2 may occur in the insulating region 811 (e.g., near the middle of the insulating region 811). Since the insulating region 811 is removed (see FIG. 12) to separate the semiconductor devices from one another, the peak of the profile P2 is no longer present in the resulting semiconductor device 10. As shown in FIG. 16, the sections of the profiles P1 and P2 correspond to the insulating region 811 are illustrated in the dashed lines to indicate they are absent in the resulting semiconductor substrate 110.

With continued reference to FIG. 16 and FIG. 15, in the boundary zone Z1 of the semiconductor substrate 110 which is an area on (or near) the second side 110d of the semiconductor substrate 110, the silicon atomic percentage may decrease and the oxygen atomic percentage may increase. For the resulting semiconductor substrate 110 (the insulating region 811 has been removed), the oxygen atomic percentage may be higher than the silicon atomic percentage at the second side 110d of the semiconductor substrate 110. An atomic ratio of oxygen to silicon (O:Si) at the first side 110c of the semiconductor substrate 110 may be less than an atomic ratio of (O:Si) at the second side 110d of the semiconductor substrate 110.

FIGS. 17A-17C are schematic different cross-sectional views illustrating a semiconductor device, in accordance with some embodiments. Unless specified otherwise, like reference numerals in FIGS. 17A-17C represent like components in the embodiment shown in FIG. 15. Referring to FIG. 17A and with reference to FIG. 15, a semiconductor device 10-1 may be similar to the semiconductor device 10 shown in FIG. 15, except that the sidewall 110e′ of the semiconductor substrate 110 is substantially straight/vertical relative to the first side 110c (or the second side 110d). As mentioned in the previous paragraphs, the profile of the sidewall 110e′ of the semiconductor substrate 110 may depend on the profile of the trenches 12T (see FIG. 5). When the straight inner sidewall SW1′ is formed at the step of FIG. 5, the resulting semiconductor substrate 110 may have the straight sidewall 110e′. The bottom of the sidewall 220W of the interconnect structure 220 may (or may not) be aligned with the sidewall 110e′ of the semiconductor substrate 110.

Referring to FIG. 17B and with reference to FIG. 17A, a semiconductor device 10-2 may be similar to the semiconductor device 10-1 shown in FIG. 17A, except that the sidewall 220W′ of the interconnect structure 200 is substantially straight/vertical relative to the first side 110c of the semiconductor substrate 110. As mentioned in the previous paragraphs, the profile of the sidewall 220W′ of the interconnect structure 220 may depend on the profile of the trench 14T (see FIG. 9). When the straight inner sidewall 14W′ is formed at the step of FIG. 9, the resulting interconnect structure 220 may have the straight sidewall 220W′.

Referring to FIG. 17C and with reference to FIG. 17B, a semiconductor device 10-3 may be similar to the semiconductor device 10-2 shown in FIG. 17B, except that the sidewall 220W′ of the interconnect structure 200 and the sidewall 110e′ of the semiconductor substrate 110 may be substantially aligned (or coplanar), within process variations. When the trench 14T and the underlying trench 12T are substantially aligned to form the inner sidewall SW1′ substantially aligned with the inner sidewall 14W′, the resulting semiconductor device 10-3 may have a coterminous sidewall including the sidewall 220W′ and the sidewall 110e′.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

According to some embodiments, a semiconductor device includes a semiconductor substrate including a first side, a second side, a sidewall connected to the first and second sides, and at least one protrusion protruded from the second side, devices disposed at the first side of the semiconductor substrate, and an interconnect structure disposed over the first side of the semiconductor substrate and electrically coupled to the devices. The at least one protrusion and the semiconductor substrate are made of a same material.

According to some embodiments, a semiconductor device includes a semiconductor substrate including a first element and a second element, devices disposed at an active side of the semiconductor substrate, and an interconnect structure disposed over the active side of the semiconductor substrate and electrically coupled to the devices. A first atomic ratio of the second element to the first element at the active side of the semiconductor substrate is less than a second atomic ratio of the second element to the first element at a back side of the semiconductor substrate.

According to some embodiments, a manufacturing method for a semiconductor device includes: forming an insulating region inside a semiconductor substrate, wherein the insulating region extends along a first direction, and the semiconductor substrate comprises device regions and a sacrificial region surrounding the device regions; forming an insulating via in the sacrificial region of the semiconductor substrate and connected to the insulating region, wherein the insulating via extends along a second direction substantially perpendicular to the first direction; forming devices and an interconnect structure over the semiconductor substrate and in the device regions, wherein the interconnect structure is electrically coupled to the devices; forming a window in the sacrificial region of the semiconductor substrate to expose the insulating via; removing the insulating via and the insulating region through the window; and separating the device regions from one another.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a semiconductor substrate comprising a first side, a second side, a sidewall connected to the first and second sides, and at least one protrusion protruded from the second side, wherein the at least one protrusion and the semiconductor substrate are made of a same material;
devices disposed at the first side of the semiconductor substrate; and
an interconnect structure disposed over the first side of the semiconductor substrate and electrically coupled to the devices.

2. The semiconductor device of claim 1, wherein a surface roughness of the sidewall of the semiconductor substrate is less than that of the second side of the semiconductor substrate.

3. The semiconductor device of claim 1, wherein a height of the at least one protrusion is less than a maximum lateral dimension of the at least one protrusion.

4. The semiconductor device of claim 1, wherein:
the semiconductor substrate comprises a first element and a second element,
at the first side of the semiconductor substrate, an atomic percentage of the first element is higher than an atomic percentage of the second element, and
at the second side of the semiconductor substrate, an atomic percentage of the first element is less than an atomic percentage of the second element.

5. The semiconductor device of claim 4, wherein:
the semiconductor substrate further comprises a boundary zone in proximity to the second side, and
in the boundary zone, the atomic percentage of the second element increases along a direction from the first side toward the second side of the semiconductor substrate.

6. The semiconductor device of claim 1, wherein a sidewall of the interconnect structure is laterally offset from the sidewall of the semiconductor substrate.

7. The semiconductor device of claim 1, wherein a top width of the interconnect structure is less than a bottom width of the interconnect structure.

8. A semiconductor device, comprising:
a semiconductor substrate comprising a first element and a second element, wherein a first atomic ratio of the second element to the first element near an active side of the semiconductor substrate is less than a second atomic ratio of the second element to the first element near a back side of the semiconductor substrate;
devices disposed at the active side of the semiconductor substrate; and
an interconnect structure disposed over the active side of the semiconductor substrate and electrically coupled to the devices.

9. The semiconductor device of claim 8, wherein a sidewall of the semiconductor substrate connected to the active side and the back side is smoother than the back side.

10. The semiconductor device of claim 8, wherein the semiconductor substrate comprises at least one protrusion protruded from the back side.

11. The semiconductor device of claim 8, wherein:
the semiconductor substrate further comprises a boundary zone in proximity to the back side, and
in the boundary zone, an atomic ratio of the second element to the first element increase along a direction from a side of the boundary zone close to the active side toward an opposing side of the boundary zone close to the back side.

12. The semiconductor device of claim 8, wherein a maximum lateral dimension of the interconnect structure is less than a maximum lateral dimension of the semiconductor substrate.

13. The semiconductor device of claim 8, wherein a sidewall of the interconnect structure is inclined.

14. The semiconductor device of claim 8, wherein a sidewall of the semiconductor substrate is inclined.

15. A manufacturing method for a semiconductor device, comprising:
forming an insulating region inside a semiconductor substrate, wherein the insulating region extends along a first direction, and the semiconductor substrate comprises device regions and a sacrificial region surrounding the device regions;
forming an insulating via in the sacrificial region of the semiconductor substrate and connected to the insulating region, wherein the insulating via extends along a second direction substantially perpendicular to the first direction;
forming devices and an interconnect structure over the semiconductor substrate and in the device regions, wherein the interconnect structure is electrically coupled to the devices;
forming a window in the sacrificial region of the semiconductor substrate to expose the insulating via;
removing the insulating via and the insulating region through the window; and
separating the device regions from one another.

16. The manufacturing method of claim 15, wherein forming the insulating region inside the semiconductor substrate comprises:
performing an implantation process on the semiconductor substrate to form an implanted region inside the semiconductor substrate; and
performing a thermal treatment on the implanted region.

17. The manufacturing method of claim 15, wherein forming the insulating region inside the semiconductor substrate comprises:
forming the insulating region into sections, wherein the sections are laterally separated by at least one pillar portion, wherein when forming the devices and the interconnect structure, the at least one pillar portion releases charges generated during processes for forming the devices and the interconnect structure into a ground electrical potential.

18. The manufacturing method of claim 17, further comprising:
breaking the at least one pillar portion after removing the insulating via and the insulating region to form at least one protrusion at a back side of the semiconductor substrate.

19. The manufacturing method of claim 15, further comprising:
forming a trench between the window and the devices regions, wherein the device regions are surrounded by the trench;
forming a protective layer in the trench before removing the insulating via and the insulating region; and
after removing the insulating via and the insulating region, removing the protective layer to separate the device regions from one another.

20. The manufacturing method of claim 15, further comprising:
epitaxially growing a substrate material on a front side of the semiconductor substrate after forming the insulating region inside the semiconductor substrate and before forming the insulating via in the sacrificial region of the semiconductor substrate.
